(19) United States
(12) Patent Application Publication
(10) Pub. No.: US 2009/0047203 A1
(43) Pub. Date: Feb. 19, 2009

(54) METHOD FOR PRODUCING MONOCRYSTALLINE METAL OR SEMI-METAL BODIES

(76) Inventors: Matthias Mueller, Jena (DE); Uwe Sahr, Nuernberg (DE)

Correspondence Address: STRIKER, STRIKER & STENBY, 103 EAST NECK ROAD, HUNTINGTON, NY, 11743, US

(21) Appl. No.: 12/191,807

(22) Filed: Aug. 14, 2008

(30) Foreign Application Priority Data
Aug. 16, 2007 (DE) 10 2007 038 851.0

(51) Int. Cl. C01B 33/00; C30B 11/14

(52) U.S. Cl. 423/348; 117/83

(57) ABSTRACT

The invention relates to the production of bulky monocrystalline metal or semi-metal bodies, in particular of a monocrystalline Si ingot, using the vertical gradient freeze (VGF) method by directional solidification of a melt in a melting crucible having a polygonal basic shape.

According to the invention, the entire bottom of the melting crucible is completely covered with a thin seed crystal plate made of the monocrystalline semi-metal or metal. Throughout the procedure, the bottom of the melting crucible is kept below the melting temperature of the semi-metal or metal in order to prevent melting of the seed crystal plate.

Monocrystalline ingots produced in this way are distinguished by a low average dislocation density of for example less than 10⁵ cm⁻², allowing the production of very efficient monocrystalline Si solar cells.

The present application claims the priority of German patent application No. 10 2007 038 851.0 “Method for Producing Monocrystalline Metal or Semi-Metal Bodies”, filed on 16 Aug. 2007, the entire content of which is hereby incorporated by way of reference.

### FIELD OF THE INVENTION

The present invention relates generally to the production of comparatively large monocrystalline material blanks using the vertical gradient freeze method (referred to hereinafter also as the VGF method), in particular of monocrystalline metal or semi-metal bodies, preferably of monocrystalline silicon for applications in photovoltaics or of monocrystalline germanium crystals.

### BACKGROUND OF THE INVENTION

Solar cells should have the highest possible degree of efficiency for the conversion of solar radiation into electrical current. This efficiency is dependent on a plurality of factors, such as inter alia on the purity of the raw material, the infiltration of impurities during the crystallization from the surfaces of contact between the crystal and the crucible into the crystal interior, the infiltration of oxygen and carbon from the surrounding atmosphere into the crystal interior and also from the direction of growth of the individual crystal grains.

The production of monocrystalline silicon using the Czochralski method is known in the art. This method can be used to produce monocrystalline silicon having a low dislocation density and a defined orientation. Solar cells produced in this way are distinguished by a high degree of efficiency. Nevertheless, this method is relatively costly both with regard to energy and with regard to production-related aspects. It can be used to produce only round crystals, causing very high cutting waste in the production of the conventionally rectangular or square-shaped solar cells. As soon as a dislocation occurs in the method, the dislocation is multiplied very markedly owing to the high temperature gradient prevailing during the method, so that the material has hardly any advantages even for photovoltaics compared to multicrystalline silicon.

Various variants of the production of bulky multicrystalline silicon ingots by directional solidification of molten silicon in a melting crucible are also known in the art. A common feature of these known production methods is the fact that the heat is withdrawn from the crystal melt at the bottom thereof and a crystal thus grows from the bottom upward. Owing to the typically rapid solidification and the absence of a seed crystal, the crystal grows not as a monocrystal but rather in a multicrystalline manner. A block is formed consisting of a large number of crystal grains, of which each grain grows in the direction of the locally prevailing temperature gradient.

If then in the molten silicon volume the isotherms of the temperature field extend not in a planar manner and not parallel to the bottom of the crucible, i.e. horizontally, no planar phase boundary will form and the individual grains will not grow parallel to one another and perpendicularly from the bottom upward. This is accompanied by the formation of linear crystal imperfections even within the monocrystalline regions. These undesirable crystal imperfections can be made visible as so-called etch pits by slightly etching polished surfaces (for example on silicon wafers). A number of linear crystal imperfections increased as described hereinbefore thus leads to an increased etch pit density.

It is a long-known requirement to minimize the etch pit density, which can be influenced by a plurality of factors, inter alia by setting a planar phase boundary. The etch pit density is therefore also a measure as to how successful the attempt has been to ensure pillar-type growth of the Si grains by way of the planar phase boundary. Since the establishment of the heat exchange method (HEM) as a first method suitable for mass production, efforts have been made to avoid the drawback of an almost punctiform heat sink at the base of the crucible (as may be inferred for example from U.S. Pat. No. 4,256,530) and to achieve a perpendicular heat flow from the top downward in the molten silicon.

There are therefore various solutions which aim as a first step to create a heat sink extending over the entire area of the base of the crucible (cf. for example EP 0 631 832, EP 0 996 516, DE 198 55 061). The present invention assumes that a flat heat sink of this type is provided.

EP 0 218 088 A1 discloses a device for producing columnar solidified metal melts by pouring or casting a metal melt into a mold with subsequent solidification in a directional temperature field. The mold is in this case surrounded by a jacket heater having a meandering conduction path course. The reversal regions of the horizontally extending individual conduction paths are bent away outward from the mold. Nevertheless, the resistance caused by the connecting points between individual graphite plates of the jacket heater must be compensated for by increasing the size of the cross section accordingly, and this is complex and cannot be carried out precisely.

EP 1 162 290 A1 discloses a method and a device for directionally solidifying a metal or semi-metal melt in a mold, below the base of which a cooling means is disposed to supply heat of fusion and to dissipate the solidification heat during the directional solidification. During the melting period there is introduced in the horizontal direction while the base heating means is switched on, between said base heating means and the cooling means, an isolation gate valve which interrupts a visible connection between the base heating means and the cooling means. During the subsequent solidification phase the isolation gate valve is at least partly removed in the horizontal direction. This method can be used to produce only multicrystalline semi-metal or metal bodies having a comparatively large dislocation density.

DE 198 55 061 discloses a corresponding melting furnace for producing multicrystalline silicon.

German patent application DE 10 2006 017 622.7 in the name of the applicant, which was filed on 12 Apr. 2006 with the title “Method and Device for Producing Multicrystalline Silicon” (granted as DE 10 2006 017 622 B4), the content of which is hereby expressly included by way of reference, discloses a method for producing multicrystalline silicon using the VGF method. The melting crucible is in this case filled with lumpy Si raw material in such a way that the inner walls of the melting crucible are covered by Si plates which were cut from a previous Si ingot. This can greatly reduce the risk of damage to container inner walls caused by sharp-edged, lumpy silicon. To compensate for the volumetric shrinkage during the melting-in of the Si feedstock introduced into the melting crucible, an annular crucible attachment is attached to said melting crucible and said crucible attachment is also filled up with the Si feedstock.

German patent application DE 10 2006 017 621.9 in the name of the applicant, which was filed on 12 Apr. 2006 with the title “Device and Method for Producing Monocrystalline or Multicrystalline Materials, in particular Multicrystalline Silicon”, and corresponding U.S. patent application Ser. No. 11/692,005 “Device and method for the production of monocrystalline or multicrystalline materials, in particular multicrystalline silicon”, filed on Mar. 27, 2007, the whole content of which are hereby expressly incorporated by way of reference, disclose the production of multicrystalline silicon using the VGF method. Provided around the circumference of the melting crucible is a jacket heater which generates an inhomogeneous temperature profile corresponding to the temperature gradient formed at the center of the crucible. The heat output of the jacket heater decreases from the upper end toward the lower end of the crucible. The jacket heater consists of a plurality of parallel heating webs extending so as to meander vertically or horizontally. The heat output of the webs is adjusted by varying the conductor cross section. To avoid local supercooling at corner regions of the crucible, conductor cross section narrowings (constrictions) are provided at the reversal regions of the meandering course of the webs.

U.S. Pat. No. 4,404,172 discloses the production of monocrystalline semiconductor materials by directional solidification using the vertical gradient freeze (VGF) method, a comparatively small monocrystalline seed crystal being arranged at the center of a cylindrical and comparatively slender melting crucible having a conical base. EP 0 372 794 B1 discloses a corresponding method.

German patent specification DD 298 532 A5 discloses a method for growing quartz seed crystals using the hydrothermal method, wherein a plurality of plate seed parts are joined together to minimize edge stresses in a clamping mount so as to be flush at the rims and subsequently exposed to the hydrothermal crystal growth conditions. The joined-together plate seed parts grow together to form a homogeneous, defect-free monocrystal which is used as a starting material for defect-free seed crystal plates having a relatively large surface area for subsequent batches.

U.S. Pat. No. 4,381,214 discloses a method for producing relatively large seed crystals by joining together by soldering two relatively small seed crystal plates which are offset from each other in the direction of crystallization and exposing the crystal composite thus formed to crystal growth conditions. The relatively large seed crystal can be separated off from the monocrystal produced in this way.

WO 2007/084934 A2, corresponding to US 2007/0169684 A1 and US 2007/0169684 A1, discloses a method for producing a square-bottomed Si ingot by directional solidification. Prior to the introduction of the Si melt, the base of the melting crucible is in this case completely covered with a plurality of monocrystalline Si plates which act as seed crystal plates. The directions of crystallization of adjacent Si seed crystal plates can also alternate with one another. The temperature at the base of the melting crucible is in this case controlled so as to prevent complete melting of the seed crystal plates.

N. Stoddard et al., “Casting Single Crystal Silicon: Novel Defect Profiles from BP Solar's Mono²™ Wafers”, Solid State Phenomena Vols. 131-133 (2008), pages 1-8, online at http://www.scientific.net, discloses the characterization of Si crystals produced using the aforementioned method, wherein use was made of a melting crucible having a bottom area of 690×690 mm². Dislocation densities of from 7×10⁴ cm⁻² to 3×10⁵ cm⁻² were measured in some of the experiments, wherein dislocation densities of just 10³ cm⁻² were even achieved in central wafers of a brick. However, all the particulars relate merely to large areas within the wafer.

EP 0 887 442 A1 and EP 0 748 884 A1 disclose a method for producing a polycrystalline Si ingot by directional solidification in a melting crucible, wherein prior to the introduction of a lumpy Si raw material, the base of the melting crucible is completely lined with a plurality of monocrystalline Si seed crystal plates.

Patent Abstracts of Japan, publication No. 10-007493 and English translation thereof disclose a corresponding method. Patent Abstracts of Japan, publication No. 10-194718 and English translation thereof disclose a corresponding method wherein the Si melt is produced in an external melting crucible and poured into the melting crucible.

Patent Abstracts of Japan, publication No. 2007-022815 and English translation thereof disclose a corresponding method wherein the base of the melting crucible is completely lined with monocrystalline Si seed crystals prior to the introduction of lumpy Si raw material.

### SUMMARY OF THE INVENTION

The object of the present invention is to provide an economical method for the cost-effective production of high-quality, low-dislocation monocrystalline material blanks by directional solidification, in particular using the VGF method and in particular of monocrystalline metal or semi-metal bodies, preferably of monocrystalline silicon.

Thus, the present invention starts from a method for producing a monocrystalline metal or semi-metal body by directional solidification, in particular using the vertical gradient freeze method (VGF method), preferably of monocrystalline silicon bodies, in which method a semi-metal or metal raw material is melted in a melting crucible to form a melt and the melt is directionally solidified under the action of a temperature gradient pointing (extending) in a vertical direction, from the upper end of the melting crucible to the lower end thereof, to form the monocrystalline metal or semi-metal body.

In this method, the bottom of the melting crucible is covered, prior to the introduction of the semi-metal or metal raw material or of a semi-metal or metal melt into the melting crucible, with a thin monocrystalline seed crystal plate layer having a crystal orientation parallel to the vertical direction of the melting crucible. In this case, the temperature of the bottom of the melting crucible is kept throughout the process, including the phase of the overall directional solidification to form the monocrystalline semi-metal or metal body, at a temperature below the melting temperature of the raw material in order to prevent melting of the seed crystal plate layer in any case down to the bottom of the melting crucible.

The crystal orientation of the monocrystalline seed crystal plate layer is parallel to the desired crystal orientation of the semi-metal or metal body to be produced. Thus, the seed crystal plate layer can according to the invention define in a simple but reliable manner the directional solidification of the melt to form a monocrystalline body having a crystal orientation in the vertical direction or perpendicular to the bottom of the melting crucible. The temperature of the bottom of the melting crucible can be monitored and controlled or regulated in a suitable manner, for example by controlling or regulating the temperature of a heating means provided in the region of the bottom, the temperature of a cooling means provided in the region of the bottom, the position of a crucible mounting plate in relation to a heating means or cooling means provided therein, the position of an adjustable radiation shield or the like. Suitable control or regulation, so that the temperature of the bottom is below the melting temperature of the semi-metal or metal, can ensure that the seed crystal plate layer reliably defines the crystal orientation.

The seed crystal plate layer can be formed in one piece (integrally) or can comprise a plurality of seed crystal plates which are arranged directly adjoining one another on the bottom of the melting crucible in order completely to cover said bottom. Suitable for this purpose are simple geometric shapes which combine well to form closed areas, such as in particular rectangular or square bottoms of the seed crystal plates.

The seed crystal plates preferably have identical thickness in order to suppress the formation of dislocations at the interface between the seed crystal plate layer and melt during the directional solidification of the melt. The thickness dimensions are in this case preferably such that temperature fluctuations in the region of the bottom of the melting crucible, such as occur in particular owing to time constants of the control or regulation, can under no circumstances cause melting-through of the seed crystal plate layer down to the bottom of the melting crucible. In principle, the thickness of the seed crystal plate layer should however preferably be minimized in order to minimize the production costs.

The seed crystal plate layer thus has a shape which is substantially defined by the vessel cross section which is defined by the bottom and side walls of the melting crucible. The seed crystal plate layer is preferably a separated-off part of a monocrystal that is produced in a suitable prior process, as will be described hereinafter, and that has dimensions corresponding to the total vessel cross section of the bottom surface of the melting crucible, thus allowing the bottom of the crucible to be completely covered.

In this method, the thin monocrystalline seed crystal plate layer, which completely covers or lines the bottom of the melting crucible, comprises a plurality of thin monocrystalline seed crystal plates arranged directly adjoining or abutting one another and having the same dimensions or an individual monocrystalline seed crystal plate in which at least one dislocation line is formed, which divides the individual monocrystalline seed crystal plate into at least two seed crystal plate sub-portions each having the same width in one or two directions perpendicular to the vertical direction.

According to the invention, the monocrystalline metal or semi-metal body produced by directional solidification is divided, by sawing along at least one sawing line extending parallel to the crystal orientation, into a plurality of monocrystalline metal or semi-metal bodies, the start of the respective sawing line being selected in such a way that said start is defined either by the edge of a seed crystal plate or by a respective dislocation line within the individual monocrystalline seed crystal plate. During the directional solidification for forming the monocrystalline metal or semi-metal body, the edges of the plurality of seed crystal plates or the at least one dislocation line, which is formed within an individual seed crystal plate completely covering the bottom of the melting crucible, result in dislocation lines following the course of the edges or of the at least one dislocation line and extending in the direction of crystal growth. Because the monocrystalline metal or semi-metal body produced using the method according to the invention is broken down along these dislocation lines into smaller blocks, the resulting smaller blocks made of the monocrystalline metal or semi-metal material have a greatly reduced dislocation or etch pit density. The monocrystalline metal or semi-metal blocks produced in this way are thus suitable for demanding applications requiring low dislocation or etch pit density, for example for the production of monocrystalline silicon cells for photovoltaics.

Complex tests carried out by the inventors have in this case revealed that the method according to the invention specifically fills a gap in the monocrystalline silicon market for applications in photovoltaics. The reason for this is on the one hand that the dislocation or etch pit density for monocrystalline silicon wafers produced using the method according to the invention is even zero or in practice, owing to inevitable process parameter fluctuations, is not excessively great, but rather lies in an average range of at most 10⁵ cm⁻² which has proven particularly advantageous for producing highly efficient solar cells. Whereas the production of dislocation-free, monocrystalline silicon using the CZ method is possible only at comparatively high costs, multicrystalline silicon produced in accordance with the prior art using comparatively cost-effective methods usually has a high dislocation density well above 10⁵ cm⁻², resulting in a reduced degree of efficiency of <15.5%. The method according to the invention can fill this gap existing in the prior art, thus allowing the economical production of multicrystalline silicon having a dislocation density lying within an acceptable average range.

Without wishing ultimately to be tied down to this theoretical explanation, the inventors currently assume that specifically the controlled introduction of defined dislocation lines into an extensive ingot provides the necessary marginal conditions to ensure a dislocation or etch pit density in the resulting monocrystalline material, which density can on use of monocrystalline seed plates from the CZ (Czochralski) method be zero but is, in the event of inevitable disturbances of the procedure or in the event of multiple use of seed plates or in the event of use of material as the seed plate that was produced from a growth process first using seed plates from the CZ method, in an average range of at most 10⁵ cm⁻². The much higher dislocation or etch pit density prevailing in the region of the dislocation lines is therefore, using the method according to the invention, subsequently of no consequence, as the smaller monocrystalline blocks are separated off (cut) precisely along these dislocation (offset) lines.

The ratio of the bottom area of the melting crucible to the bottom area of the smaller seed crystal plates or the dislocation line-free regions of the individual seed crystal plate plays an important part in this. Preferably, the bottom area of the melting crucible is selected so as to be as large as possible and should allow for example sixteen (=4×4) 6-inch bricks or twenty five (=5×5) 6-inch bricks to be cut out from an ingot. Melting crucibles having dimensions of 720×720 mm or 880×880 mm are preferred for this purpose. According to the invention, particularly preferably two or four seed crystal plates or dislocation line-free sub-portions of the individual seed crystal plate are distributed uniformly onto this bottom area.

The seed crystal plates can in this case be produced by a separate process enabling a very low dislocation or etch pit density, for example using the known Czochralski method. Preferably, a single, extensive seed crystal having an identical bottom area to the melting crucible is separated off from an ingot produced by directional solidification and using a plurality of seed crystal plates of this type, without said seed crystal being separated into smaller monocrystalline seed crystal blocks along the edges of the seed crystal plates used for the production thereof or along the respective dislocation line.

The present invention thus starts from a device having a fixed crucible and a heating means for melting on the silicon contained in the crucible. In this case, the heating means and/or thermal insulation of the device is configured so as to form in the crucible a temperature gradient in the longitudinal direction. This normally takes place as a result of the fact that the bottom of the crucible is kept at a lower temperature than the upper end thereof. Furthermore, in the case of a device of this type, the heating means has a jacket heater for suppressing a heat flow perpendicular to the longitudinal direction, i.e. directed horizontally outward.

In this case, the jacket heater is a single-zone heater which is configured in such a way that its heat output decreases in the longitudinal direction from the upper end toward the lower end in order at least to help to maintain the temperature gradient formed in the crucible. In other words, by varying the heat output of the jacket heater in the longitudinal direction of the crucible in a continuous or discrete way, the formation of a predetermined temperature gradient in the crucible is at least assisted. This temperature gradient is defined in the melting crucible by differing temperatures of a cover heater or top heater and a bottom heater in a manner known per se. In this case, the temperature of the bottom heater at the bottom of the melting crucible is relatively low, in particular below the melting temperature of the silicon to be processed. Expediently, the bottom heater does not in this case necessarily extend over the entire bottom of the crucible. Although the formation of a planar phase boundary in the material to be crystallized, for example silicon, can be achieved most precisely using a bottom heater extending over the bottom of the crucible, a phase boundary which is in practice sufficiently planar can also be achieved using an annular bottom heater which in the crystallization phase is very well adapted, with regard to its drop in temperature over the process time, to the temperature profile of the jacket heater.

According to the invention, the temperature gradient between the top or the crucible and bottom is reproduced by the heat output, which varies in the longitudinal direction of the melting crucible, of the jacket heater, thus forming over the entire cross section of the crucible, in particular also in the region of the corners of the polygonal crucible, a planar phase boundary between silicon which has already crystallized out and the still molten silicon is, i.e. a horizontally extending phase boundary. This allows a further reduction of the dislocation density in the monocrystalline semi-metal or metal ingot.

Furthermore, according to the invention, no complex measures are required for thermal insulation between the crucible and jacket heater, because the graphite crucible surrounding the quartz crucible is adequate in order sufficiently to make the temperature profile generated by the jacket heater uniform. The term “sufficient homogenization of the temperature profile” means in this case in particular that as a result of the high thermal conductivity of the outer crucible material, graphite, local temperature differences relating to the heat irradiated by the jacket heater are compensated for. The vertical temperature profile which thus forms in the graphite crucible wall is transferred almost unaltered through the crucible wall of the quartz crucible, which is a poor conductor of heat, to the inner wall of the quartz crucible. At the contact surface between the molten silicon and quartz crucible, the temperature falls monotonously and approximately linearly from the top downward. As a result, a planar, horizontal phase boundary between the silicon which has crystallized out and the still molten silicon can be ensured despite the omission of a thermal insulation material layer. With the same external dimensions of the crystallization system, this facilitates an overall larger cross section of the crucible and also a greater height of the crucible and thus according to the invention the provision of bulkier silicon ingots, resulting in considerable cost advantages. The single-zone jacket heater according to the invention having a temperature profile which can be adjusted in a defined manner over the jacket height is particularly advantageous in the production of monocrystalline silicon if use is made of quartz crucibles of a height of more than approximately 250 mm, in particular more than approximately 300 mm and most particularly preferably more than 350 mm.

The heat output of the flat heating element surrounding the crucible, in particular a jacket heater, can according to the invention be suitably set using simple measures, such as for example by varying the geometrical cross section of the jacket heater. In particular, the jacket heater can in this way easily be adapted to the geometry-related thermal properties of the crucible.

Preferably, the crucible has a polygonal cross section, most particularly preferably a rectangular or square cross section, thus allowing polygonal, in particular rectangular or square, elements, preferably silicon elements, to be cut out with advantageously low wastage. The device according to the invention is therefore based on the departure from the conventional concept of using a rotationally symmetrical melting crucible for producing monocrystalline silicon. In contrast to the prior art, the heater arranged around the crucible has the same contour as the crucible. A for example square-shaped crucible is therefore surrounded by a square-shaped heater. The conventional heat insulation layer between the heater and crucible is dispensed with.

According to a further embodiment, the heat output of the single-zone jacket heater decreases in the longitudinal direction of the crucible from the top of the crucible downward in accordance with the temperature gradient at the center of the crucible. In particular, the heat output of the jacket heater decreases per unit of length at exactly the same ratio at which the temperature gradient at the center of the crucible decreases. According to the invention, this exact, in particular proportional reproduction of the temperature gradient at the center of the crucible over the entire circumference thereof is a simple way of ensuring planar phase boundaries between silicon which has already crystallized out and still molten silicon over the entire cross section of the crucible, in particular also in corner regions of the crucible.

According to a further embodiment, the jacket heater defines or maintains a plurality of planar isotherms perpendicular to the longitudinal direction of the crucible. The resulting planar phase boundary over the entire cross section of the crucible leads to an advantageous reduction of crystal imperfections and thus to an advantageously low etch pit density of silicon wafers produced in accordance with the invention.

In particular in the case of crucibles having a rectangular or square cross section, increased heat losses were noted owing to a larger irradiating surface area per unit of volume. Such increased heat radiation losses occur in toned-down form also in the case of polygonal crucibles having a non-rectangular or non-square cross section. To compensate for such undesirable increased heat losses, the heat output of the jacket heater is higher in corner regions of the crucible or alternatively a distance between the crucible wall and the jacket heater in the corner regions of the crucible is selected so as to be smaller. The heat output of the jacket heater can in this case be increased constantly or in one or more discrete steps in the corner regions. Alternatively, the distance between the crucible wall and the jacket heater can be reduced in size constantly or in one or more steps. In particular, the jacket heater can be formed so as to be constantly curved in the corner regions, with a minimum distance on a notional extension of a line from the center of the crucible to the respective corner of the crucible, this minimum distance being less than in regions of the crucible wall outside the respective corner region.

According to a further embodiment, in particular in the case of crucibles having a rectangular or square cross section, the jacket heater comprises heating elements which are arranged around the lateral surfaces of the crucible and have a meandering course in the longitudinal direction of the crucible or perpendicularly thereto. In this way, a comparatively uniform impingement of heat on the crucible wall can be achieved while still allowing the electronic configuration of the jacket heater easily to be varied in accordance with the temperature gradient in the melting crucible. In this case, a gap width between the webs of the meandering course of the jacket heater is expediently selected in such a way that the graphite crucible wall, which is a good conductor of heat, itself leads to sufficient smoothing of the temperature profile. The gap width between webs of the jacket heater thus depends in particular also on the thermal conductivity of the material or materials of the inner crucible, for example the quartz crucible, and of the outer support crucible, for example the graphite crucible. Expediently, the gap width is in this case selected in such a way that resulting inhomogeneity of the temperature profile on the wall of the crucible is less than a predetermined deviation in temperature which is preferably less than approximately 5 K, more preferably less than approximately 2 K and even more preferably less than approximately 1 K.

According to a first embodiment, the heating elements are configured as rectangular webs which extend perpendicularly to the longitudinal direction, have a meandering course in the longitudinal direction of the crucible and the conductor cross sections of which increase from the upper end toward the lower end of the crucible in a plurality of discrete steps. A jacket heater configured in this way can be shaped in a suitable geometrical formation by simple connecting of pre-shaped individual parts, in particular made of graphite, or casting of a suitable heat conductor material.

Expediently, the webs of the jacket heater extend in this case with a meandering course equidistantly and parallel to one another. The webs extending horizontally or perpendicularly to the longitudinal direction thus define isotherms which extend at the same level over the entire circumference of the crucible and thus automatically lead to the formation of planar, horizontal phase boundaries in the crucible. The course direction of the webs is in this case inverted at reversal regions opposing the corner regions of the crucible. The geometry of the reversal regions, in particular the conductor cross sections thereof, thus provides a simple parameter in order purposefully to define the thermal conditions in the corner regions of the crucible.

In particular in the case or crucibles having a rectangular or square cross section, the jacket heater comprises heating elements which are arranged around the lateral surfaces of the crucible and have a meandering course in the longitudinal direction of the crucible or perpendicularly thereto. In this way, a comparatively uniform impingement of heat on the crucible wall is achieved while still allowing the electrotechnical configuration of the jacket heater easily to be varied in accordance with the temperature gradient in the melting crucible. In this case, a gap width between the webs of the meandering course of the jacket heater is expediently selected in such a way that the graphite crucible wall, which is a good conductor of heat, itself leads to sufficient smoothing of the temperature profile. The gap width between webs of the jacket heater thus depends in particular also on the thermal conductivity of the material of the inner crucible (for example quartz crucible) and of the outer support crucible (for example graphite crucible). Expediently, the gap width is in this case selected in such a way that resulting inhomogeneity of the temperature profile on the wall of the crucible is less than a predetermined deviation in temperature which is preferably less than approximately 5 K, more preferably less than approximately 2 K and even more preferably less than approximately 1 K.

In particular in the case of crucibles having a rectangular or square cross section, particular preventative measures can be provided in the region of the corners in order to ensure there too the striven-for horizontal isotherms. Simple reversals in the form of vertical heating webs in the case of heating webs otherwise extending in a horizontal, meandering manner can lead in the region of the diagonal of the reversal regions, without further measures to reduce the size of the conduction cross section, to a conduction cross section which is locally increased in size and thus to a reduced heat output with the consequence of a lower surface temperature on the heater. Isothermal behavior could thus not be ensured for each longitudinal coordinate of the crucible. At the corners there would then be an undesirable fall in temperature with adverse repercussions (stresses in the corners, resulting high defect density and microcracks leading to yield losses). According to the invention, various measures are possible to compensate for such deviations from the desired isothermal behavior for each longitudinal coordinate. The distance between the crucible wall and the jacket heater in the corner regions of the crucible can be reduced in size constantly or in one or more steps, since the demand for isothermal behavior in principle exists only in the crystallization phase. In particular, the jacket heater can be formed so as to be constantly curved in the corner regions, with a minimum distance on a notional extension of a line from the center of the crucible to the respective corner of the crucible, this minimum distance being less than in regions of the crucible wall outside the respective corner region.

According to a preferred further embodiment, a conductor cross section of the webs is in this case narrowed or constricted at the reversal regions of the meandering course in the diagonal direction in such a way that it is identical to the conduction cross section of the web before or after the respective reversal region. This leads to maintenance of the electrical resistance and thus to the same heat output or surface temperature in the reversal region of the webs as in the region of the horizontally extending webs.

According to a further embodiment, the narrowings or constrictions of the conductor cross section at the reversal regions are formed in a controlled manner by a plurality of perforations or recesses in or out of the web material that are arranged to distributed transversely to the conductor cross section. As a result of the geometry and the dimensions of the perforations or recesses, the conductor cross section or the electrical resistance in the reversal regions can thus be adapted to that of the webs. The course directions of the perforations or recesses are in this case variants which can all lead to the homogenization or smooting of the horizontal temperature distribution over the circumference of the crucible in each height coordinate. In the case of an overall rectangular course of the webs, the perforations or recesses can in particular extend along a diagonal connecting the corner regions of the webs. Overall, it is expedient if the plurality of perforations or recesses extend mirror-symmetrically or almost mirror-symmetrically about a notional mirror axis at the center of the gap between two mutually adjacent webs.

According to a second embodiment of the present invention, the heating elements are formed as rectangular webs which extend in the longitudinal direction and the conductor cross section of which extends, from the upper end toward the lower end of the crucible, continuously or in a plurality of discrete steps. In this case, all of the webs extending in the longitudinal direction or vertically are identical in their configuration, so that, viewed in the longitudinal direction of the crucible, a large number of planar, horizontal isotherms are defined by the jacket heater in a substantially continuous or discrete manner. In this case, the gap width between the webs is, as described hereinbefore, selected in such a way that the material of the crucible, which material is a good conductor of heat, ensures sufficient standardization of the temperature profile between the webs of the jacket heater. In any case, the regions between the webs do not lead to deviations from the monotonous and almost linearly extending rise in temperature in the increasing longitudinal coordinate of the crucible, locations at which the material to be crystallized enters into contact with the inner crucible wall being considered here in all cases.

According to a further embodiment, the jacket heater is made from individual segments which if appropriate, for example in the case of local damage or when the jacket heater is to be configured differently, can be dismantled and replaced by a different segment. A modular construction of this type has proven successful in particular for jacket heaters consisting of a plurality of heating webs having a meandering course. In this case, the segments must be connected so as to ensure at the connecting points unimpeded current flow, and this necessitates certain compromises in the selection of the type of connection and the materials. In particular, the segments can be detachably joined together with the aid of connecting elements, such as for example wedges or stoppers having an identical or slightly greater coefficient of thermal expansion, or with the aid of other positive-locking, friction-locking or non-positive-locking elements, in particular screws or rivets. According to another embodiment, the segments can also be joined together with a material-to-material fit, for example by soldering or welding.

A further aspect of the present invention relates to the use of a method, as described hereinbefore, for producing a monocrystalline silicon ingot by means of a vertical gradient freeze crystal pulling method (VGF method) as a raw material for the production of photovoltaic constructional elements.

A further aspect of the present invention relates to monocrystalline silicon wafers, produced by sawing from a silicon ingot produced by carrying out the method described hereinbefore, wherein according to the invention the average dislocation density (etch pit density; EPD) is lower than 10⁵ cm⁻². This value is achieved on each wafer which is cut out from the ingot produced using the method according to the invention. Edge, base and cover regions of the ingot and also regions of the ingot containing SiC or SiN enclosures are excluded from this, as these regions of a Si ingot are not sawn up to form wafers in accordance with the prior art either. Depending on whether the seed plates, which originally stem from a Czochralski process, are used repeatedly or were obtained from the first time from an ingot which was grown using the original Czochralski seed plates having a dislocation density of zero, values even much lower than 10⁵ cm⁻² are achieved as the average dislocation density of a wafer. These average dislocation densities of a wafer are less than 5×10⁴ cm⁻², more preferably less than 10⁴ cm⁻², even more preferably less than 10³ cm⁻² and even more preferably less than 10² cm⁻². Owing to the inevitable process parameter fluctuations, average dislocation densities of a wafer of less than 10³ cm⁻² or even less than 10² cm⁻² are not measured on each wafer which was sawn out from an ingot produced using the method according to the invention, but rather only in a fraction thereof. Tests carried out by the inventors have in this case revealed that under otherwise identical process conditions such an advantageously low average dislocation density can be achieved only by use of a seed crystal plate layer, as described hereinbefore, during the directional solidification of a melt in a bulky melting crucible. For measuring the aforementioned dislocation densities, edge, base and cover regions of the ingot and also regions of the ingot containing SiC or SiN enclosures were excluded in all cases.

### OVERVIEW OF THE FIGURES

The invention will be described hereinafter by way of example and with reference to the appended drawings revealing further features, advantages and objects to be achieved. In the drawings:

FIG. 1 is a schematic cross sectional view of a device for producing monocrystalline silicon in accordance with the present invention;

FIG. 2a is a schematic sectional view showing the repelnishmend of the melting crucible prior to the melting-on in the case of a method in accordance with the present invention;

FIG. 2b is a schematic sectional view showing the repelnishmend of the melting crucible prior to the melting-on in the case of a further method in accordance with the present invention;

FIG. 2c is a schematic sectional view showing the repelnishmend of the melting crucible prior to the melting-on in the case of a further method in accordance with the present invention;

FIG. 2d is a schematic sectional view showing the repelnishmend of the melting crucible prior to the melting-on in the case of a further method in accordance with the present invention;

FIG. 3a is a schematic plan view showing the orientation of the seed crystal plates used in the case of the method according to FIG. 2a in relation to the sawing lines along which the monocrystalline Si ingot is divided after the solidification into smaller blocks, according to a first embodiment of the present invention;

FIG. 3b is a schematic side view showing the geometry according to FIG. 3a;

FIG. 3c is a schematic plan view showing the orientation of the seed crystal plates used in the case of the method according to FIG. 2a in relation to the sawing lines along which the monocrystalline Si ingot is divided after the solidification into smaller blocks, according to a second embodiment of the present invention;

FIG. 3d is a schematic side view showing the geometry according to FIG. 3c;

FIG. 4 shows the course of the boundary between the monocrystalline phase and multicrystalline phase in the case of a modified embodiment of the present invention used for producing extensive seed crystal plates from comparatively small seed crystal plates;

FIG. 5 is a schematic plan view showing a jacket heater with a meandering course of the heating webs in the case of a method in accordance with the present invention;

FIG. 6a is a schematic view showing measures for narrowing or constricting the conductor cross section according to a further embodiment of the present invention;

FIG. 6b shows measures for narrowing or constricting the conductor cross section according to a further embodiment of the present invention;

FIG. 6c shows measures for narrowing or constricting the conductor cross section according to a further embodiment of the present invention;

FIG. 7a-7c are schematic plan views showing differing types of connection for connecting webs of the jacket heater according to FIG. 5; and

FIG. 7d is a perspective view showing a further type of connection for connecting webs of the jacket heater according to FIG. 5.

Throughout the drawings, identical reference numerals denote identical or substantially equivalent elements or groups of elements.

### DETAILED DESCRIPTION OF PREFERRED EXEMPLARY EMBODIMENTS

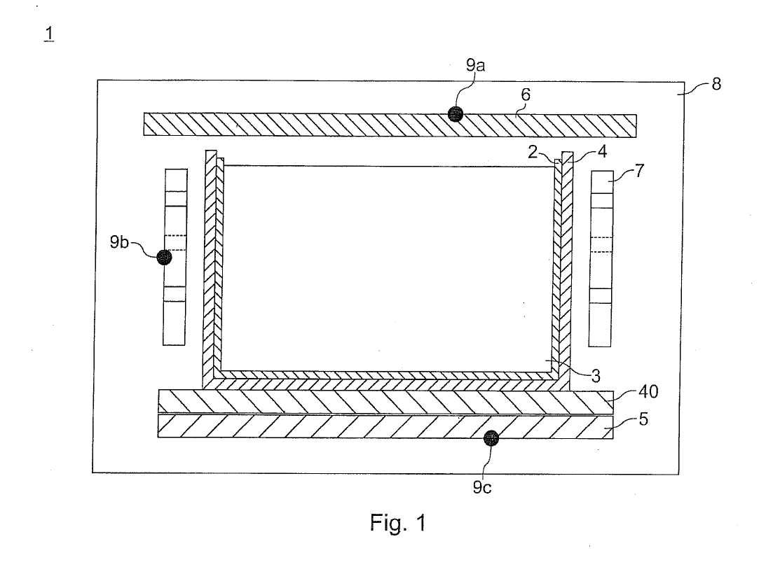

FIG. 1 shows an example of a crystallization system for the directional solidification of a melt using a vertical gradient freeze (VGF) method, which system is used in a method according to the invention. The system, which is denoted overall by reference numeral 1, has a crucible having a square cross section. According to FIG. 1, the crucible is formed by a quartz crucible 2 which is received so as to abut closely for support in a correspondingly formed graphite container 4. The silicon 3 received in the crucible 2 thus does not come in contact with the graphite container 4. The crucible is arranged upright, so that the crucible walls extend in the direction of gravity. The quartz crucible 2 is a commercially available quartz crucible having a bottom area of for example 570×570 mm, 720×720 mm, 880×880 mm or 1,040×1,040 mm and has an inner coating as a separating layer between SiO₂ of the crucible and silicon. Most particularly preferably, the quartz crucible has a bottom area of 720×720 mm.

Above and below the crucible is a cover (top) heater 6 or a bottom heater 5, there being arranged between the crucible and the bottom heater 5 a crucible mounting plate 40, made for example of graphite, which in the illustration is indicated merely schematically. In this case, the actual mount of the aforementioned crucible is formed in such a way that a narrow gap is formed between the bottom heater 5 and the crucible mounting plate 40 supporting the crucible. The core zone of the crucible is surrounded by a flat heating element, namely a jacket heater 7 which will be described hereinafter in greater detail. The jacket heater extends substantially over the entire height of the crucible. In the case of the VGF crystallization method, all heaters 5-7 are temperature-regulated. For this purpose, the surface temperatures of the heaters are detected by pyrometers 9a-9c at a suitable point, as illustrated by way of example in FIG. 1, and input into a control unit which controls or regulates in a suitable manner the constant current flowing through the heaters 5-7.

Alternatively or additionally, the plate denoted by reference numeral 5 can also be configured as a cooling plate through which a coolant can flow under the action of a suitable controller or regulator. The crucible mounting plate 40 can then be configured as an insulation plate, made for example of graphite. In this case, the actual mount of the crucible is formed in such a way that a narrow gap is formed between the crucible mounting plate 40 supporting the crucible and the cooling plate 5.

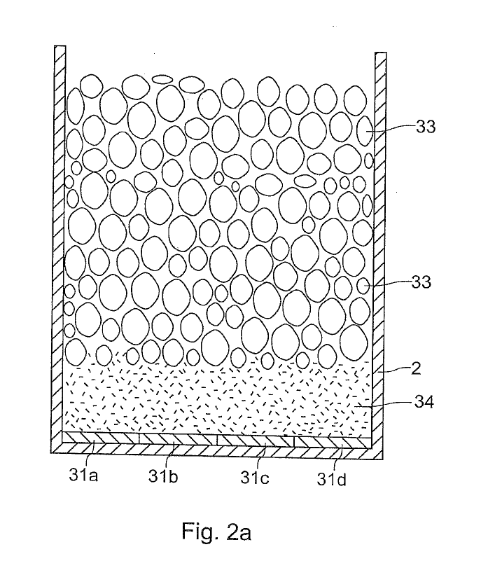

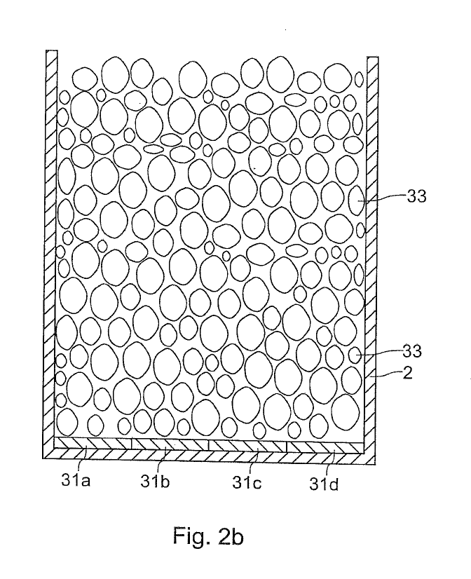

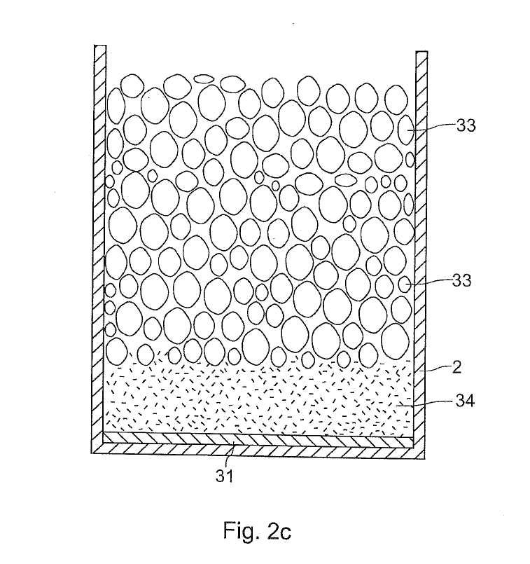

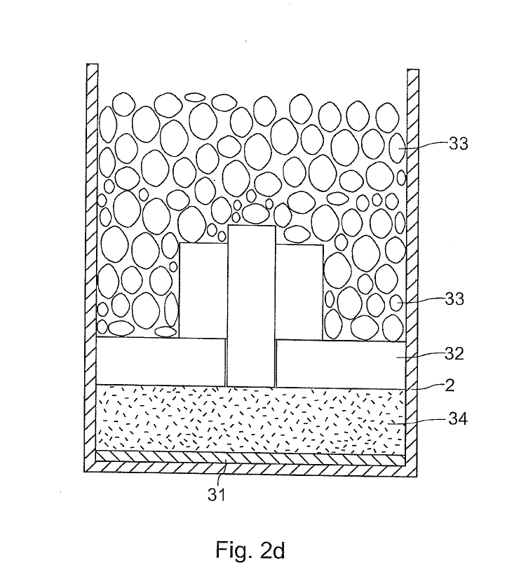

The VGF method can according to the invention be carried out in such a way that the melting crucible is first filled up with a silicon feedstock, as will be described hereinafter with reference to FIGS. 2a-2d. Firstly, all heaters 5-7 are brought up to differing temperatures in such a way that all of the silicon contained in the crucible is melted on. For crystallizing out the silicon melt, the bottom heater 5 and the cover heater 6 are regulated in such a way that the cover heater 6 is kept at a temperature above the melting temperature of the silicon to be processed and the bottom heater 5 is brought first to a temperature just below the melting temperature of the silicon to be processed. This leads first to crystallizing-out at the bottom of the crucible. As the base plate 40, which was introduced to make the temperature uniform, extends over the entire surface area of the bottom of the crucible, the silicon crystallizes out uniformly not only at the center but rather on the entire bottom of the crucible. Subsequently, the temperature of each of the three heaters shown parallel to the other heaters is brought down, thus allowing the melt in the crucible continuously to solidify upward, the phase boundary between material which has already crystallized out and the still molten material extending horizontally, i.e. perpendicularly to the direction of gravity.

According to FIG. 1, no further thermal insulation is provided between the crucible wall 2, 4 and the jacket heater 7. Instead, according to the invention, suitable geometrical configuration of the jacket heater 7 ensures, as will be described hereinafter in greater detail, that the temperature gradient defined by the cover heater 6 and the bottom heater 5 in the crucible is supported or maintained by the heat output emitted by the jacket heater. For this purpose, the heat output emitted by the jacket heater is locally not constant but rather decreases in the longitudinal direction of the crucible from the upper end toward the lower end, in accordance with the temperature gradient at the center of the crucible during the gradual solidification of the silicon melt.

Procedures for filling up (replenishment of) the melting crucible with a silicon feedstock in the case of a method in accordance with the present invention will be described hereinafter with reference to FIGS. 2a to 2d.

According to FIG. 2a, a silicon feedstock made up of lumpy or granular silicon 33 is introduced into the interior of the crucible 2. Examples of suitable raw materials include:
silicon plates which were sawn off from the sides of earlier molten ingots and thus automatically have substantially the dimensions of the inner walls of the crucible, i.e. can substantially completely cover said inner walls;
large, coarse pieces of silicon originating from a recycling process (cleansing process) of waste material;
silicon fragments, in particular from previous batches;
silicon wafer or wafer fragments;
silicon granules (of medium grain size) in the form of commercially available raw material;
silicon granules (fine grain size) in the form of commercially available raw material.

The silicon feedstock extends according to FIG. 2a prior to the melting-on substantially up to the upper edge of the crucible 2. According to FIG. 2a, Si granules 34 of medium or fine grain size are introduced below the coarse silicon feedstock 33. According to FIG. 2a, the bottom of the melting crucible 2 is substantially completely covered with a plurality of seed crystal plates 31a-31d made of monocrystalline silicon of comparatively low thickness. The crystal orientation of these seed crystal plates 31a-31d is vertical, i.e. parallel to the desired direction of growth of the monocrystalline silicon to be produced.

The seed crystal plates 31a-31d preferably have an identical thickness and directly adjoin (abut) one another, so that the bottom of the melting crucible is completely lined or covered. The seed crystal plates 31a-31d are preferably rectangular or square, although in principle any other geometries allowing substantially complete coverage of the bottom of the melting crucible are admissible.

For melting on the silicon, the cover heater 6 heats the silicon feedstock from above to a temperature above the melting temperature of the silicon. In addition, energy can also be supplied via the lateral jacket heater 7 and the bottom heater 5. The silicon feedstock is therefore first melted onto the upper edge of the crucible. The melted-on, liquid silicon then runs or seeps downward through the silicon feedstock located therebelow in order to collect at the bottom of the quartz crucible 2.

Finally, the state according to FIG. 1 is achieved, in which the silicon melt has filled the quartz crucible 2 up to the upper edge thereof. Throughout the procedure, care is taken to ensure that the temperature of the bottom of the melting crucible 2 remains at a temperature below the melting temperature of the silicon, so that the seed crystal plates 31a-31d do not melt on the bottom of the crucible 2, in any case do not melt through down to the bottom of the crucible 2. Slight melting onto the upper side of the seed crystal plates 31a-31d is entirely desirable, provided that this does not impair the crystal growth orientation defined by the crystal orientation of the seed crystal plates 31a-31d.

Subsequently, the directional cooling and solidification of the liquid silicon to form a monocrystalline silicon ingot commences. Now the bottom heater is kept at a defined temperature below the melting temperature of the silicon, for example at a temperature of at least b 10 K below the melting temperature. At the bottom of the melting crucible, the crystal growth is then initiated. After a short time an equilibrium temperature profile is established and the initiated crystal growth stops. In this state the cover heater and bottom heater have the desired difference in temperature which is equal to the difference in temperature between the top and bottom of the jacket heater. Now the heat output of the heaters 5-7 is reduced, each parallel to one another. Columnar growth of a monocrystalline Si block ensures, the direction of growth of the resulting Si monocrystal being defined by the crystal orientation of the seed crystal plates 31a-31d. In accordance with the horizontal phase boundary, the growth takes place parallel and perpendicularly from the bottom upward. The monocrystalline Si ingot thus obtained is then cooled to room temperature and removed.

At no point in the procedure is the direction of the prevailing temperature gradient in the melting crucible 2 reversed.

FIGS. 2b to 2d show further variants for filling (replenishing) the melting crucible with a Si feedstock in the case of a method in accordance with the present invention. According to FIG. 2b, the entire melting crucible 2 is filled uniformly up to the upper edge with a coarse silicon feedstock 33, as described hereinbefore. In accordance with FIG. 2a, the bottom of the melting crucible 2 is covered with a plurality of seed crystal plates 31a-31d made of monocrystalline silicon according to FIG. 2b as well.

The melting crucible according to FIG. 2c is basically filled as described hereinbefore with reference to FIG. 2a. By contrast, the entire bottom of the melting crucible is covered with an individual, comparatively thin seed crystal plate 31 which is made of monocrystalline silicon and also fills the corner regions of the melting crucible 2.

According to FIG. 2d, the bottom of the melting crucible is covered with an individual, comparatively thin seed crystal plate 31 made of monocrystalline silicon. Si granules 34 of medium or fine grain size are introduced thereabove. Subsequently, comparatively large uniformly shaped silicon bodies 32 are introduced into the crucible in the horizontal and vertical extensions, these bodies 32 extending preferably from the center up to the inner walls of the crucible and from the center up to the upper edge of the crucible. These bodies 32 are either qualitatively usable remaining portions of a Si ingot of a previous batch or else related raw material having a geometry of this type (for example cylindrical pieces). Owing to the thermal conductivity of the Si bodies 32, which is higher than that of the feedstock made of lumpy silicon, thermal bridges are thus created in the interior of the Si feedstock and heat can be purposefully introduced into the center and into the immediate vicinity of the bottom of the container. As during melting-on the heat is provided mainly by the cover heater and the jacket heater, the Si feedstock can as a whole be melted on more uniformly. The bodies 32 should, as they originate by separating off from a Si ingot of a previous batch, be subjected beforehand to cleansing (typically an etching process), which is also referred to as a recycling process, in order to be reusable.

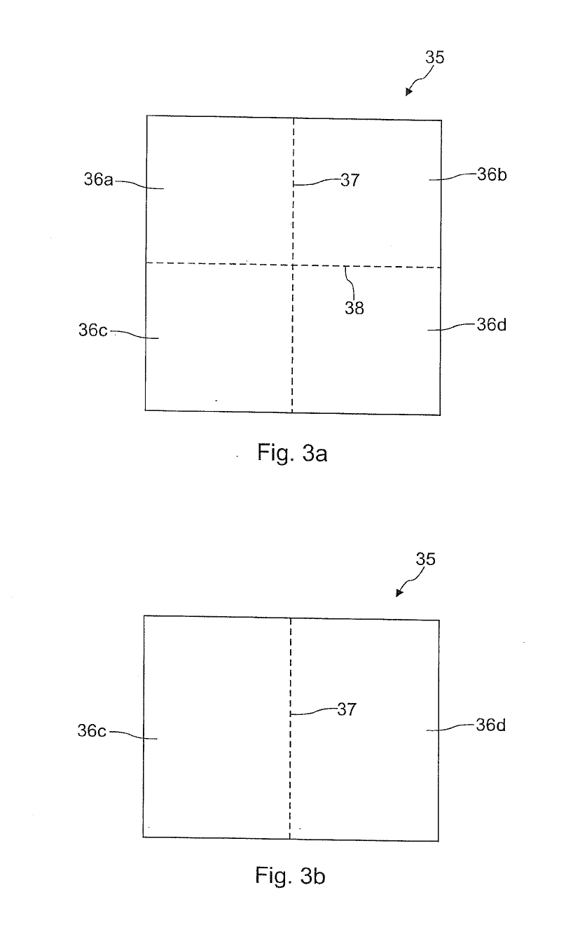

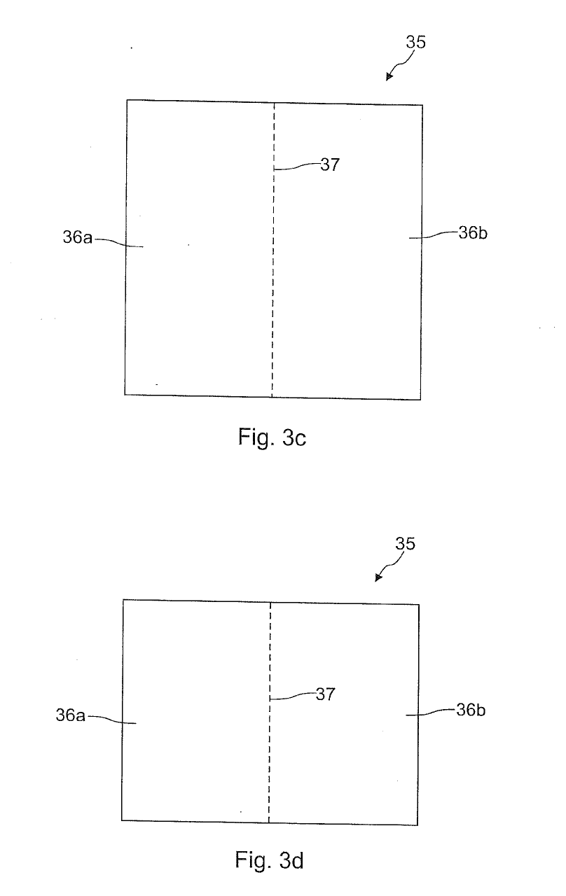

FIG. 3a is a plan view of the arrangement of the seed crystal plates 31a-31d in the melting crucible in the case of a method according to a first embodiment of the present invention. It may be seen that the rims of the four seed crystal plates 31a-31d directly abut one another, so that the bottom of the melting crucible is completely covered, even in the corner regions thereof. Lines 37 and 38 denote in plan view sawing lines along which the Si ingot having a square cross section is divided after the solidification into four smaller, square blocks having identical bottom areas, for example by sawing using a wire saw. Of course, depending on the size of the ingot, a plurality of square blocks can also be produced by appropriate sawing using a wire saw (for example 25 5″ blocks or 16 6″ blocks or other quantities in accordance with the bottom area of the ingot). As may be seen from FIG. 3a, the sawing lines extend exactly along the rims of the seed crystal plates 31a-31d or, if relatively large seed crystal plates are used, within the ingot volume which has grown in a monocrystalline manner. In this way, the dislocations which can be detected in a horizontal sectional plane of the ingot or of the blocks are significantly reduced. The direction of growth of the dislocations is typically vertical in accordance with the direction of movement of the phase boundary during the crystallization. FIG. 3b is a schematic side view of the course of the sawing line 37 through the monocrystalline silicon ingot 35. This method is preferably used in a melting crucible having dimensions of 720×720 mm (height: for example 450 mm), so that by sawing along the sawing lines 37, 38 wafers having a rim length of six inches are formed while allowing for sufficient wastage.

FIG. 3c is a plan view of the arrangement of the seed crystal plates 31a-31d in the melting crucible in the case of a method according to a second embodiment of the present invention. It may be seen that the rims of the two seed crystal plates 31a-31b directly abut each other, so that the bottom of the melting crucible is completely covered, even in the corner regions thereof. Lines 37 denote in plan view sawing lines along which the Si ingot having a square cross section is divided after the solidification into two smaller, rectangular blocks having identical bottom areas, for example by sawing using a wire saw. As may be seen from FIG. 3c, the sawing line 37 extends exactly along the rims of the seed crystal plates 31a-31b. In this way, the dislocations which can be detected in a horizontal sectional plane of the ingot or of the blocks are significantly reduced. The direction of growth of the dislocations is typically vertical in accordance with the direction of movement of the phase boundary during the crystallization. FIG. 3d is a schematic side view of the course of the sawing line 37 through the monocrystalline silicon ingot 35. This method is preferably used in a melting crucible having dimensions of 720×720 mm (height: for example 450 mm), so that by sawing along the sawing line 37 and a central perpendicular thereto wafers having a rim length of six inches are formed while allowing for sufficient wastage.

The comparatively thin, monocrystalline seed crystal plates described hereinbefore can be produced in different ways. Thus, said seed crystal plates can for example be cut out from a monocrystalline blank produced in a Czochralski method, which plates can be drawn or pulled with diameters of from 300 to 450 mm and lengths of up to 1,000 mm with the direction of growth in the 111 direction or 110 direction. As blanks produced in this way conventionally have a circular cross section, the wastage during the cutting-out of rectangular or square seed crystal plates is comparatively large.

More cost-effective is thus the production of the seed crystal plates by cutting the seed crystal plates from a monocrystalline Si ingot from a previous batch, which ingot is produced using the method according to the invention by directional solidification. In this case, the bottom of the further melting crucible used for this purpose can be completely covered with a plurality of seed crystal plates, most particularly preferably with two or four seed crystal plates having identical dimensions, before the raw material to be melted or according to a further variant the melt to be directionally solidified is introduced. The edges of the seed crystal plates define after the directional solidification the start of the sawing lines along which the seed crystal plates subsequently to be used are separated off.

According to a preferred embodiment of the present invention, the seed crystal plate which is directionally solidified in the further melting crucible is however not sawn into smaller seed crystal plates but rather left as a stock of seed crystal plates from which relatively thin seed crystal plates can be separated off as required by sawing in a direction perpendicular to the direction of crystallization or vertical direction of the further melting crucible, for example at a thickness of 30 mm. A seed crystal plate of this type thus has the same cross-sectional area as the melting crucible used in the subsequently produced batch. As however use was made, to form these seed crystal plates by directional solidification, of a plurality of seed crystal plates directly adjoining one another, offset lines (dislocation lines) are in each case formed in this seed crystal plate along the edges of the plurality of seed crystal plates. On use of these seed crystal plates having at least one disclocation line, for directional solidification in a subsequent batch, there are then produced in the ingot a corresponding number of dislocation lines along which the ingot is then cut into smaller blocks.

It is in this case possible to cut from the ingot of a previous batch in particular also a seed crystal plate which is relatively highly contaminated. Usually, edge plates of this type are cut (separated off) from ingots and not further used. However, such edge plates can in principle be used for the method according to the invention, and this has significant cost advantages. As such contaminated edge plates do indeed usually have considerable thickness, seed crystal plates having considerable thicknesses can thus be used at almost no cost for the production of monocrystalline ingots. Obviously, care must in this case be taken to ensure that as a result of the use of the contaminated edge plates as monocrystalline seed crystal plates, the concentration of impurities remains within an acceptable range.

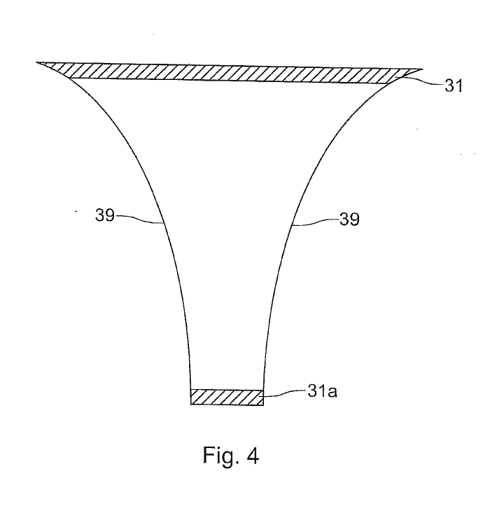

In order to allow the directional solidification of a bulky Si ingot from a comparatively small seed crystal plate using the method according to the invention for producing a larger seed crystal plate, this method can also be modified in such a way that in accordance with FIG. 4 the temperature gradient during the directional solidification causes a convex phase boundary (not shown) between the liquid and solid state, so that the cross section of the monocrystalline core region produced during the directional solidification spreads in the direction toward the upper end of the further melting crucible, as shown schematically in FIG. 4. According to FIG. 4, the method commences with the application of a comparatively small monocrystalline seed crystal plate 31a which is laid at the center of the further melting crucible at the bottom thereof. Subsequently, a Si feedstock is introduced, as described hereinbefore, melted on and directionally solidified using the modified method described hereinbefore. The envelopes 39 denote the boundary region between the central monocrystalline phase and adjoining multicrystalline phase in the Si ingot formed. These boundary lines move further and further apart from one another toward the upper edge of the further melting crucible. The seed crystal plate 31a to be used in a subsequent batch is separated off in proximity to the upper end of the Si ingot, within the monocrystalline region, and has the same surface area as the melting crucible used for the directional solidification. The ingot of the next batch is used as a stock of seed crystal plates for all subsequent batches and has the same bottom area as the melting crucible used for the directional solidification.

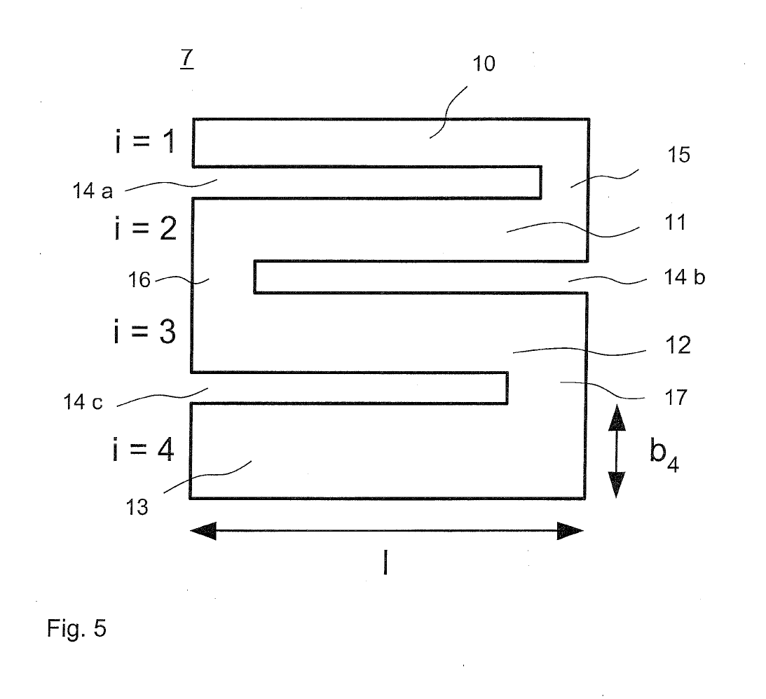

There will be described hereinafter with reference to FIGS. 5 to 7 further measures in accordance with the present invention that further assist the formation of planar isotherms in the corner regions of the polygonal, in particular rectangular or square, melting crucible during the directional solidification of the melt.

FIG. 5 shows a jacket heater segment according to a first embodiment of the present invention that is formed from a plurality of heating webs which have a rectangular profile and form a meandering course in the longitudinal direction of the crucible. More precisely, each jacket heater segment according to FIG. 5 is arranged at a constant distance from a crucible wall, so that the webs 10-13 extend exactly horizontally, perpendicularly to the longitudinal direction of the crucible. The course direction of the webs 10-13 is reversed at the reversal regions 15-17. According to FIG. 5, the cross section of the webs 10-13 increases from the upper end toward the lower end of the crucible in discrete steps. The heat output of the top web 10 is thus the highest and decreases in discrete steps, as defined by the conductor cross sections of the webs 11, 12, to the lowest heat output defined by the cross section of the bottom web 13.

In the case of an alternative embodiment (not shown), the widths of the webs 10-13 are constant, although their thickness, viewed perpendicularly to the drawing plane of FIG. 5, increases in discrete steps from the upper end toward the lower end of the crucible.

A constant current flows through a jacket heater consisting of a plurality of jacket heater segments. In this case, the horizontally extending webs 10, 11, 12 and 13 define isotherms extending over the entire width of the crucible. A plurality of jacket heaters of this type according to FIG. 5 are arranged at in each case identical distances around the circumference of the crucible, so that the isotherms defined by the webs 10-13 extend over the entire cross section of the crucible in order thus to define planar, horizontal isotherm surfaces.

Although FIG. 5 shows the jacket heater 7 to have a total of four transverse webs, according to the invention any other desired numbers of heating webs can be used. The optimum number of heating webs results from the desired standardization of the temperature profile in the crucible and on the crucible wall. The width of the gaps 14a-14c between the webs 10-13, the selected distance of the jacket heater 7 from the crucible wall and the thermal properties of the crucible wall are in this case, in particular, included for configuring the jacket heater. The graphite crucible 4 (cf. FIG. 1), which is a good conductor of heat having sufficient strength and the quartz crucible contained therein lead in this case to a certain smoothing of the vertical temperature profile. The foregoing parameters are selected in such a way that the position of a web of the jacket heater on the temperature profile at the interface between the silicon and the lateral inner wall of the quartz crucible is substantially no longer ascertainable.

Generally, in the case of the jacket heater according to FIG. 5 having a length of the webs l, a width of the webs bᵢ (wherein i denotes the running index of the web) and a thickness d (perpendicular to the drawing plane of FIG. 2), the electrical resistance of a heating web having the index i is given by:

Ri˜l/Ai, wherein

Ai=bi×d.

For the cross-sectional areas, the following then applies:

A1<A2<A3<A4.

From this, the following applies to the resistances of the individual meanders: R1<R2<R3<R4.

Consequently:

T1>T2>T3>T4.

Therefore, in the vertical direction, a temperature profile is obtained with a temperature increasing in discrete steps upward. When a constant current intensity flows through the heating meander, a lower temperature is generated in the webs having a large cross section (corresponding to a low electrical resistance) than in the webs having a small cross section (corresponding to a high electrical resistance).

As will be readily apparent to a person skilled in the art, the variation of the conductor cross section through which current flows from web to web can also be achieved by varying the web thickness d instead of the web width b, as described hereinbefore.

In an exemplary embodiment according to FIG. 5, the following area ratios are established:

| | |
|---|---|
| A1/A1 | 1 |
| A2/A1 | 1.055 |
| A3/A1 | 1.11 |
| A4/A1 | 1.165 |

These area ratios produce the following resistance ratios:

| | |
|---|---|
| R1/R1 | 1 |
| R2/R1 | 0.948 |
| R3/R1 | 0.901 |
| R4/R1 | 0.858 |

As may be seen in FIG. 5, the width of the heat conductor also varies in the reversal regions 15 to 17 in a corresponding manner. The width of the reversal region 15 is thus less than the width of the reversal region 16, which is in turn less than the width of the reversal region 17. The variation of the widths of the reversal regions follows the temperature profile to be formed.

In view of the reversal regions 15-17 of the jacket heater 7 according to FIG. 5, local cross section enlargements occur in the material through which current flows. Without countermeasures, these would result in a low temperature at the corner regions of the crucible. According to the invention, this is counteracted by purposeful narrowing (constriction) of the conductor cross section in the reversal regions. In particular, such a constriction of the conductor cross section can also compensate for increased heat losses in the corner regions of the crucible, for example due to higher heat radiation losses caused by the larger irradiating surface area per unit of volume.

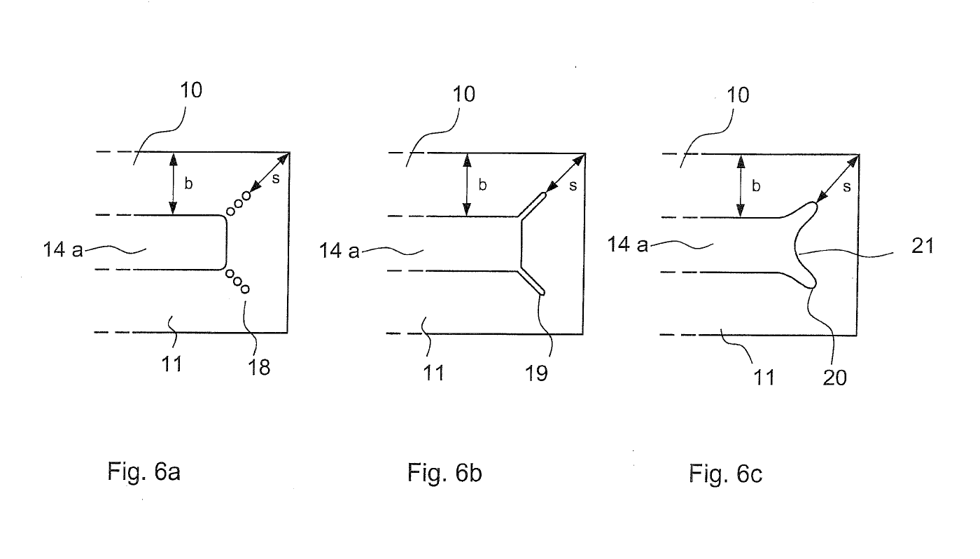

According to FIG. 6a, a plurality of perforations or recesses 18 are arranged along the diagonals of the respective reversal region, aligned on the diagonal. Overall, the perforations or recesses 18 are arranged mirror-symmetrically to the center line of the gap 14a. Obviously, a plurality of such rows of perforations or recesses can also be provided in the reversal region. The resistance ratio between the web 10, 11 extending in the horizontal direction and the associated reversal region can be set appropriately by configuring and selecting the number of perforations or recesses.

In the embodiment according to FIG. 6b, rectangular recesses are formed along the diagonal. Selecting the s/b ratio allows an optimum resistance ratio to be established.

According to FIG. 6c, narrowing (constricting) recesses are formed along the diagonal, a concave inwardly curved course of the edge being formed between the recesses 20. The foregoing recesses 11, 20 can in particular be formed by milling from the material of the heating conductor.

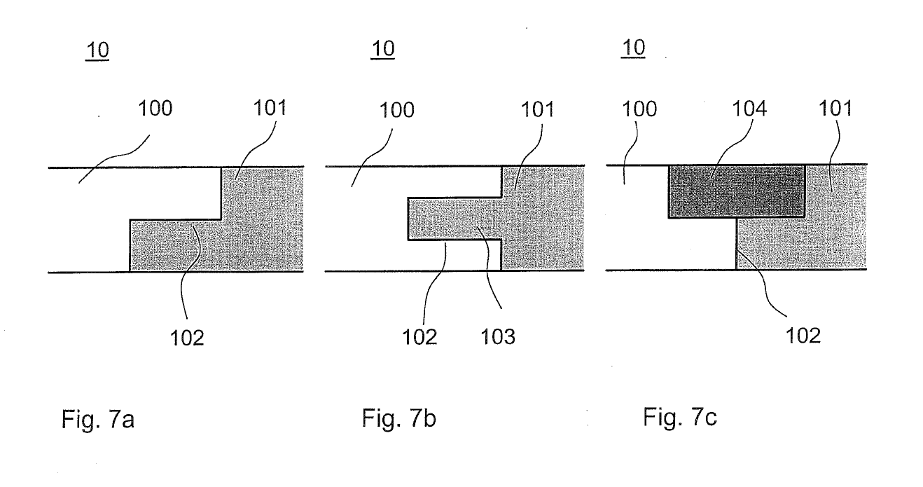

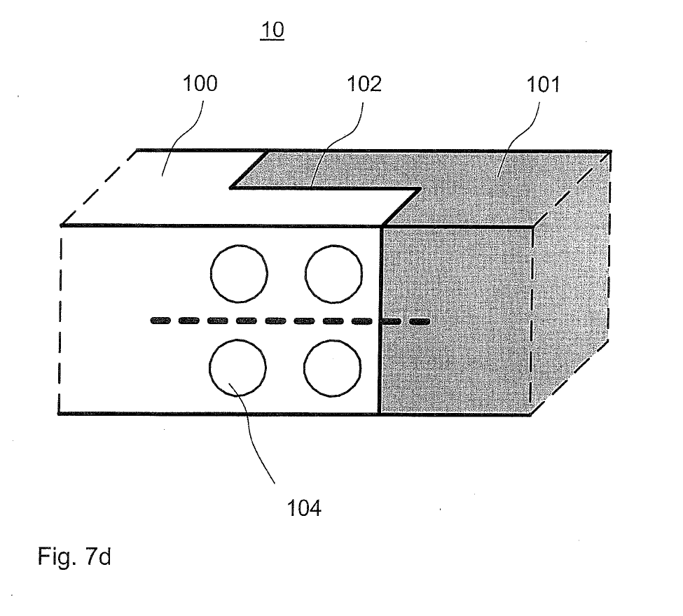

Preferably, the webs of the jacket heater are made of graphite. As according to the invention crucibles having a bottom area of 720×720 mm or even larger crucibles are used and correspondingly large graphite blocks for producing the webs of the jacket heater either are not available at all or are available only at a comparatively high price, the webs of the jacket heater segment are according to a further embodiment formed, as will be described hereinafter in detail with reference to FIG. 7a to 7d, from again a plurality of smaller segments. In this case, care must be taken to ensure a substantially unimpeded current flow through the connecting points between the jacket heater segments and also between the smaller segments. Connecting surfaces which engage with one another in a positive-locking manner and have rectangular geometry are used for this purpose.

According to FIG. 7a, the ends of the heating segments 100, 101 are substantially L-shaped in their configuration, so that a stepped interface 102 is formed between both segments 100, 101. According to FIG. 7b, a central U-shaped recess is formed at the end of the segment 100 and formed at the opposing end of the segment 101 is a corresponding inverted U-shaped projection 103 which fits into the recess of the segment 100 so as to abut closely. An interface 102 having a central projection is thus formed between the segments 100, 101. According to FIG. 7c, a right parallelepiped recess is formed at the ends of the segments 100, 101 to receive a connecting element 104.

FIG. 7d is a perspective plan view of the connection according to FIG. 7a, the segments 100, 101 being penetrated by cylindrical connecting elements 104. The connecting elements 104 can be made of the material of the segments 100, 1001. The connecting elements 104 can engage with the segments 100, 101 in a positive-locking, friction-locking or non-positive locking manner. The connecting elements 104 can alternatively be made of a different material having an identical or slightly greater coefficient of thermal expansion than the material of the segments 100, 101.

According to a series of tests carried out by the inventors, two right parallelepiped heater segments made of graphite were joined together in the manner according to FIG. 7d and a temperature profile was recorded along the dotted line according to FIG. 7d with local resolution. For reasons of corrosion, the measurements were taken in a normal air atmosphere and at a lower temperature than the subsequent operating temperature under current throughput. The measured uniformity of the temperature profile at this low temperature level is however completely transferrable to the subsequent higher operating temperature level.

The temperature fluctuations which can be achieved in the connecting region are of the order of magnitude of less than approximately ±5° Celsius.

### Exemplary Embodiment

To produce a monocrystalline silicon ingot, a quartz crucible having a square basic shape 720×720 mm in dimensions and 450 mm in height was used. The bottom of the melting crucible was covered with a seed crystal plate layer which comprised four individual seed crystal plates and the crystal direction of which was parallel to the side walls of the melting crucible. The seed crystal plates were cut from a Si monocrystal produced using the Czochralski method. Silicon granules of fine or medium grain size were then added to this seed crystal plate layer up to the upper edge of the melting crucible. The Si granules were melted on from above using a cover heater. In this case, the jacket heaters were also switched on, whereas the bottom of the melting crucible was not heated. Use was made of a melting-down rate of 5 cm/h which according to other series of tests could be varied in the range between 1 cm/h and 10 cm/h. During melting-on, the solid/liquid phase boundary was first lowered over the crucible from the top downward until the seed crystal plate had been melted on. In this case, the amount of heat introduced from above was comparatively large whereas the heat losses at the bottom of the melting crucible were relatively low in order thus to allow suitably rapid, energy-efficient melting-on.

In a second step the amount of heat dissipated at the bottom of the melting crucible was increased and at the same time the amount of heat introduced from above reduced. This allows the direction of movement of the solid/liquid phase boundary to be reversed again. It was possible to observe the directional solidification of a monocrystalline Si ingot, the crystalline structure of which was defined by that of the seed crystal plates. In this case, the ratio between the amount of heat introduced from above and the amount of heat dissipated at the bottom of the melting crucible determines the solidification speed.

By suitably shaping the jacket heater in the region of the reversal regions of its meandering heating webs, as described hereinbefore with reference to FIGS. 5 to 7, planar isotherms could be established in particular also in the corner regions of the melting crucible.

The Si ingot thus obtained was cut along sawing lines, which extend along the edges of the seed crystal plates used for the directional solidification and perpendicularly to the direction of crystallization, into a number, corresponding to the number of seed crystal plates, of Si blocks which were each distinguished by a low average dislocation density owing to the low or missing lateral temperature gradient.

The average dislocation density of the Si wafers was determined by what is known as “dislocation etching”. For this purpose, a Si sample, which was of any desired orientation and had just been polished and cleansed, of a wafer (for example 30×30×2 mm in size) was etched slightly for 20 to 60 seconds with the aid of what is known as a “Secco” etch (etch mixture: dissolve 4.4 g of K₂Cr₂O₇ in 100 ml of water, as soon as the K₂Cr₂O₇ has complete dissolved, add 200 ml of 48% hydrofluoric acid). Alternatively, the polished wafer surface can also be achieved by a known gloss etching of the wafer. At the points at which the dislocation lines puncture the surface, characteristic etch pits are formed as a result. The density of the etch pits on the surface (etch pit density/EPD), which is specified in 1/cm² and is a conventional measure for the dislocation density of a material, is determined under a light-optical microscope in that over the entire surface of the sample, in sections of for example 300×300 μm, the number of etch pits is counted and converted into the surface density. The average dislocation density of a wafer is specified as the mean value of all counted-out surfaces of the wafer samples and the surface sections of the samples, i.e. averaged over the entire examined surface of the wafer.

For each wafer, it was possible to measure an average dislocation density, i.e. a mean value of the dislocation density, of less than 1×10⁵ cm⁻² on crystals produced using the VGF method according to the invention and wafers produced therefrom, averaged substantially over the entire surface of the cleansed and polished samples of each wafer. It was thus possible to produce monocrystalline Si solar cells with a degree of efficiency greater than 15.5%, greater than 16%, greater than 16.5%, indeed greater than 17%.

### COMPARATIVE EXAMPLE

Except for the seed crystal plates covering the bottom of the melting crucible, the melting crucible was filled in an identical manner. Subsequently, the melting crucible was heated in a corresponding manner and cooled back down. Subsequently, the Si ingot was removed and examined further, in particular with regard to the dislocation density which was determined as described hereinbefore.

It was found that an average dislocation density of less than 10⁵ cm⁻² could not be achieved. It was thus not possible to produce Si solar cells with a degree of efficiency of greater than 15.5%.

### Further Exemplary Embodiments

Seed crystal plates were formed from a Si monocrystal grown using the Czochralski method in direction 110 (or else 111) and having a diameter of 450 mm by sawing along the direction of crystallization (halving) and finishing the rims so as to allow the two seed crystal plates to be laid end to end against each other. Two rectangular seed crystal plates having a thickness of 30 mm and a bottom area of 410×820 mm were formed as a result, with which the bottom of the melting crucible was completely covered. The Si ingot formed by directional solidification was used as a stock of seed crystal plates from which an individual seed crystal plate having a bottom corresponding to the bottom of the melting crucible used in subsequent batches was separated off Along the center of this seed crystal plate ran a dislocation line leading to a correspondingly extending dislocation line in the Si ingot formed by directional solidification.

It was possible to measure an average dislocation density, i.e. a mean value of the dislocation density, of less than 1×10⁵ cm⁻² on the Si crystals thus produced and wafers produced therefrom.

The segmented meandering heater configuration can, as will be readily apparent to a person skilled in the art, be used also for the heaters above and below the crucible. However, the cross sections through which current flows are expediently not varied in the case of these heaters, as the upper side and underside of the silicon ingot should be heated as uniformly as possible. The heater which is optionally provided under the bottom of the crucible assists the melting-on of lumpy silicon with the aim of a process time which is as short as possible. During the crystallization, the heater at the bottom of the crucible is however in principle not required.

The configuration of the heaters affords, in interaction with the electronically controlled reduction in temperature, in particular the following advantages:
The planar phase boundary in all crystallization phases causes a columnar, perpendicular growth of the Si grains having a homogeneous structure;
Low number of line defects in the ingot, observable on the Si wafer owing to a lower etch pit density;

Minimizing the convection flows in the still molten Si above the phase boundary and accordingly minimizing the conveyance of Si₃N₄ particles from the internally coated quartz crucible wall into the interior of the melt or minimizing the conveyance of SiC particles from the surface of the molten Si into the interior of the melt, leading in both cases to reduced enclosures in the ingot; the yield and the degree of efficiency are increased by the aforementioned minimization;
Preventing stresses in the corner region of the ingot and accordingly minimizing increased defect concentrations in the corners, avoiding stress-related microcracks which would otherwise lead in later processing steps to yield losses.

Without wishing to be tied down to the underlying theory, it is assumed that the dislocation line or dislocation lines, which are formed along the edges of the seed crystal plates or the dislocation line of the individual seed crystal plate, in the Si ingot induces or induce a medium-sized dislocation density in the region of less than 1×10⁵ cm⁻² which has been found to be ideal for the production of the solar cells with a high degree of efficiency.

Although the foregoing exemplary embodiments related for the most part to crucible heights of 450 mm, it should expressly be noted that experiments have revealed that the advantages which can be achieved by the specific configuration of the reversal regions of the meandering heating webs of the flat jacket heater, as described hereinbefore, are most particularly effective for still greater crucible heights, for example for crucible heights of 660 mm or even 760 mm, and this also further reduces the costs of producing each wafer. Furthermore, experiments have revealed that the external dimensions of the melting crucible can also be larger, as described hereinbefore, for example can be 720 mm, 880 mm or 1,040 mm.

What is claimed is:

1. A method for producing a monocrystalline metal or semi-metal body by directional solidification, comprising the steps of:
melting a semi-metal or metal raw material in a melting crucible to form a melt or introducing a semi-metal or metal melt into the melting crucible,
directional solidification of the melt under the action of a temperature gradient pointing in a vertical direction and from the upper end of the melting crucible to the lower end thereof to form the monocrystalline metal or semi-metal body,
prior to the introduction of the semi-metal or metal raw material or of the melt into the melting crucible, completely covering the bottom of the melting crucible with a thin monocrystalline seed crystal plate layer having a crystal orientation parallel to the vertical direction of the melting crucible; and
keeping the temperature of the bottom of the melting crucible at a temperature below the melting temperature of the raw material or of the melt in order to prevent melting of the seed crystal plate layer in any case down to the bottom of the melting crucible;
in which method:
the thin monocrystalline seed crystal plate layer comprises
a) a plurality of thin monocrystalline seed crystal plates of the same size arranged directly adjoining one another in order completely to cover the bottom of the melting crucible or
b) an integral monocrystalline seed crystal plate in which at least one dislocation line is formed, which divides the individual monocrystalline seed crystal plate into seed crystal plate sub-portions of the same size; and
the monocrystalline metal or semi-metal body is divided by sawing along at least one sawing line extending in parallel with the crystal orientation into a plurality of monocrystalline metal or semi-metal bodies; wherein
the start of the respective sawing line is selected in such a way that said start is defined by the edge of a seed crystal plate or by a respective dislocation line within the integral monocrystalline seed crystal plate.

2. The method as claimed in claim 1, wherein the respective seed crystal plate is cut from a monocrystalline metal or semi-metal body which was produced by directional solidification of a melt in a further melting crucible, wherein
prior to the introduction of a semi-metal or metal raw material or of the melt into the further melting crucible, the bottom of the further melting crucible is completely covered with a thin monocrystalline seed crystal plate layer having a crystal orientation parallel to the vertical direction of the further melting crucible; and
the temperature of the bottom of the further melting crucible is kept at a temperature below the melting temperature of the raw material or of the melt in order to prevent melting of the seed crystal plate layer in any case down to the bottom of the melting crucible;
the thin monocrystalline seed crystal plate layer comprises
a) a plurality of thin monocrystalline seed crystal plates of the same size arranged directly adjoining one another in order completely to cover the bottom of the melting crucible or
b) an integral monocrystalline seed crystal plate in which at least one dislocation line is formed, which divides the individual monocrystalline seed crystal plate into seed crystal plate sub-portions of the same size.

3. The method as claimed in claim 2, wherein the temperature gradient during the directional solidification of the previous batch causes a planar, horizontal phase boundary between the liquid and solid state of the semi-metal or metal.

4. The method as claimed in claim 1, wherein
at the start of the production of the seed crystal plate only a small central portion of the bottom of a further melting crucible is covered with a thin monocrystalline seed crystal plate having a crystal orientation parallel to the vertical direction of the melting crucible and
the temperature gradient during the directional solidification of a melt in the further melting crucible causes a convex phase boundary between the liquid and solid state of the semi-metal or metal, so that the cross section of the monocrystalline metal or semi-metal body produced during the directional solidification increases in size in the direction toward the upper end of the further melting crucible,
in which method
the integral monocrystalline seed crystal plate or the plurality of monocrystalline seed crystal plates being cut from the upper end or close to the upper end of the monocrystalline metal or semi-metal body thus produced.

5. The method as claimed in claim 1, wherein the respective seed crystal plate is produced by:
cutting at least two seed crystal plates having a rectangular or square basic shape from a monocrystalline metal or semi-metal body produced by zone melting or by a Czochralski method;
completely covering the bottom of a further melting crucible with said at least two seed crystal plates having a crystal orientation in parallel with the vertical direction of the further melting crucible;
melting a semi-metal or metal raw material in the further melting crucible to form a melt or introducing a semi-metal melt or metal melt into the further melting crucible;
directional solidification of the melt under the action of a temperature gradient pointing in the vertical direction and from the upper end of the further melting crucible to the lower end thereof to form a monocrystalline metal or semi-metal body; and
cutting the respective seed crystal plate from the monocrystalline metal or semi-metal body thus directionally solidified; wherein
the temperature of the bottom of the further melting crucible is kept at a temperature below the melting temperature of the raw material or of the melt in order to prevent melting of the seed crystal plate layer in any case down to the bottom of the further melting crucible.

6. The method as claimed in claim 2, wherein the respective seed crystal plate is cut from the directionally solidified monocrystalline metal or semi-metal body by sawing in a direction perpendicular to the vertical direction.

7. The method as claimed in claim 6, wherein the step of cutting the respective seed crystal plate from the directionally solidified monocrystalline metal or semi-metal body further comprises:
sawing in a direction parallel to the vertical direction, the start of the respective sawing line being selected in such a way that said start is defined either by the edge of a seed crystal plate or by a respective dislocation line within the integral monocrystalline seed crystal plate.

8. The method as claimed in claim 1, wherein the direction of the temperature gradient is never reversed during the melting of the semi-metal or metal raw material in the melting crucible and during the directional solidification of the melt in the melting crucible.

9. The method as claimed in claim 1, wherein the semi-metal is silicon and the temperature of the bottom of the melting crucible is kept below 1,400° C., more preferably below 1,380° C.

10. The method as claimed in claim 1, wherein the melting crucible has a rectangular or square cross section.

11. The method as claimed in claim 1, wherein a heating means surrounding the melting crucible comprises a top heater and a flat heating means surrounding side walls of the melting crucible, in which method:
the heat output of the flat heating means decreases during the directional solidification from the upper end toward the lower end of the melting crucible in accordance with the temperature gradient at the center of the melting crucible;
the flat heating means comprises a plurality of heating elements which in the longitudinal direction of the melting crucible or perpendicularly thereto have a meandering course; and
the heating elements being are provided as webs which extend perpendicularly to the longitudinal direction and the conductor cross sections of which increase from the upper end toward the lower end in discrete steps;
said webs being provided with a conductor cross section which is constricted at regions of reversal of the meandering course.

12. The method as claimed in claim 11, wherein the webs are provided at the reversal regions with a conductor cross section which is constricted in the diagonal direction, so that the conductor cross section is identical to the conductor cross section of an associated web before or after the respective reversal region.

13. The method as claimed in claim 12, wherein the constrictions of the conductor cross section at the reversal regions are formed by forming a plurality of perforations or recesses in or out of the web material, said plurality of perforations or recesses being distributed transversely to the conductor cross section.

14. The method as claimed in claim 1, wherein the semi-metal or metal raw material is lumpy, granular silicon which is melted on from the upper edge of the melting crucible, so that melted-on, liquid silicon runs or seeps downward through the silicon feedstock, wherein
for replenishing the melting crucible with the raw material silicon granules, preferably of medium or fine grain size, are applied to the bottom being covered by the seed crystal plate layer,
there are introduced first the silicon granules in a thin layer and subsequently large silicon plates in the horizontal orientation, so that said plates each extend from the center of the melting crucible substantially up to the inner walls thereof, and/or are introduced in the vertical orientation, so that said plates extend substantially up to the upper edge of the melting crucible,
the large silicon plates are covered by further silicon granules, and
the silicon feedstock is finally covered by smaller pieces of silicon.

15. A monocrystalline silicon wafer, produced by sawing from a silicon ingot produced by directional solidification, comprising the steps of:
melting a semi-metal or metal raw material in a melting crucible to form a melt or introducing a semi-metal or metal melt into the melting crucible,
directional solidification of the melt under the action of a temperature gradient pointing in a vertical direction and from the upper end of the melting crucible to the lower end thereof to form the monocrystalline metal or semi-metal body,
prior to the introduction of the semi-metal or metal raw material or of the melt into the melting crucible, completely covering the bottom of the melting crucible with a thin monocrystalline seed crystal plate layer having a crystal orientation parallel to the vertical direction of the melting crucible; and
keeping the temperature of the bottom of the melting crucible at a temperature below the melting temperature of the raw material or of the melt in order to prevent melting of the seed crystal plate layer in any case down to the bottom of the melting crucible;
in which method:
the thin monocrystalline seed crystal plate layer comprises
a) a plurality of thin monocrystalline seed crystal plates of the same size arranged directly adjoining one another in order completely to cover the bottom of the melting crucible or
b) an integral monocrystalline seed crystal plate in which at least one dislocation line is formed, which divides the individual monocrystalline seed crystal plate into seed crystal plate sub-portions of the same size; and
the monocrystalline metal or semi-metal body is divided by sawing along at least one sawing line extending in parallel with the crystal orientation into a plurality of monocrystalline metal or semi-metal bodies; wherein
the start of the respective sawing line is selected in such a way that said start is defined by the edge of a seed crystal plate or by a respective dislocation line within the integral monocrystalline seed crystal plate;
said monocrystalline silicon wafer having a dislocation density (etch pit density; EPD) of less than 10⁵ cm⁻².
